(19) United States
(12) Patent Application Publication
(10) Pub. No.: US 2017/0229250 A1
(43) Pub. Date: Aug. 10, 2017

(54) PEROVSKITE SOLAR CELL

(71) Applicant: National Cheng Kung University, Tainan City (TW)

(72) Inventors: Tzung-Fang Guo, Tainan City (TW); Wei-Chih Lai, Tainan City (TW)

(73) Assignee: National Cheng Kung University, Tainan City (TW)

(21) Appl. No.: 15/245,624

(22) Filed: Aug. 24, 2016

Related U.S. Application Data
(60) Provisional application No. 62/292,048, filed on Feb. 5, 2016.

(51) Int. Cl. H01G 9/20; H01L 51/42

(52) U.S. Cl. CPC H01G 9/2027; H01L 51/4226

(57) ABSTRACT

A perovskite solar cell is provided with a perovskite material layer having a first surface and a second surface opposite to the first surface; an electron transport layer disposed on the first surface; and a gold-nickel oxide layer disposed on the second surface. Furthermore, a manufacturing method of the perovskite solar cell is disclosed with steps of providing a transparent substrate; forming a gold-nickel oxide layer on the transparent substrate; and forming a perovskite material layer on the gold-nickel oxide layer.

### CROSS REFERENCE TO RELATED APPLICATIONS

This application claims the benefit of the filing date of U.S. provisional patent application Ser. No. 62/292,048, filed on Feb. 5, 2016, the disclosure of which is incorporated herein by reference.

### FIELD OF THE INVENTION

The present invention relates to a perovskite solar cell and a manufacturing method thereof, and in particular relates to a transparent electrode formed by gold-nickel oxides in a perovskite solar cell and a manufacturing method thereof.

### BACKGROUND OF THE INVENTION

Perovskite materials for the application of solar cells has excellent advantages, such as high carrier mobility, high carrier diffusion length, high absorption coefficient, and other characteristics, and are suitable for the production of high efficiency solar cells. Other advantages comprise inexpensive material cost and a simple process. Therefore, an ultrathin light absorbing layer can be produced by using a simple wet coating process and has a high power conversion efficiency (PCE). The estimated cost of electricity is only about ⅕ to ¼ of the silicon cells. Its high power conversion efficiency, low cost, and simple manufacturing process result in a significant impact in the field of solar cell technology. So far the perovskite solar cell technology is not yet mature, and a lot of basic research is rapidly expanding, causing research units of every country to invest in a lot of research and development. In recent years, the efficiency of the perovskite solar cell progresses quite fast, and the current power conversion efficiency can reach 18%.

Currently, in most published literature, a transparent conductive film (transparent conductive oxide, TCO) with a pattern formed by laser etching or exposure is first applied to an organic photovoltaic (OPV) structure. Next, a perovskite material can be combined with an n-type metal oxide, and then a suitable hole transport material (HTM) is applied to produce a perovskite solar cell, that is the general n-type metal oxide/perovskite/hole transport material stacked structure. the n-type metal oxide and the hole transport material is used as an electron transport layer and a hole transport layer, respectively, which are able to selectively help the electron/hole pairs extracted and separated from the perovskite material (charge extraction). In addition, as an inverted structure of the solar cell, the general practice is a glass substrate/indium tin oxide (glass/ITO) coated with a layer of PEDOT:PSS (poly(3,4-ethylenedioxythiophene)poly(styrenesulfonate)) as the hole transport layer, then the perovskite material is grown on the hole transport material, and a suitable electron transport material is applied to produce a solar cell.

The highest occupied molecular orbital level (HOMO) of PEDOT:PSS is 5.1 eV, which can be applied to the material of the hole transport layer for the perovskite material. In addition, the PEDOT:PSS can improve the surface characteristics of ITO for helping growth of the perovskite material later. However, the ITO easily suffers corrosion due to the acidity (pH=1.2) and moisture absorption of the PEDOT:PSS as well as the disadvantage that indium from the ITO easily diffuses into the active layer caused degradations. Therefore, the application of PEDOT:PSS as the hole transport layer for perovskite-based cells is not conducive to long-term operation, while solar cells are required to have a long period of stability in order to increase their service life.

It is therefore necessary to provide a perovskite solar cell and a manufacturing method of the perovskite solar cell, in order to solve the problems existing in the conventional technology as described above.

### SUMMARY OF THE INVENTION

A primary object of the present invention is to provide a perovskite solar cell having a gold-nickel oxide layer (Au:NiO_{X}) with chemical stability, the suitable work function, having an excellent transmittance to be used as a hole transport material which is directly connected with the perovskite material layer and used as a transparent electrode. Therefore, the perovskite solar cell can be produced without an organic hole transport layer and ITO, so that its structure is simple and has high stability, increased life, and lower consumption cost as well as higher applicability of the perovskite solar cell.

An another object of the present invention is to provide a manufacturing method of a perovskite solar cell with a step of forming the abovementioned gold-nickel oxide layer by using a rapid and easy thermal annealing process, and the forming steps of the traditional organic hole transport material and transparent conductive film ITO can be saved (omitted) so that the manufacturing process is simplified.

To achieve the above objects, the present invention provides a perovskite solar cell, comprising a perovskite material layer having a first surface and a second surface opposite to each other; an electron transport layer disposed on the first surface; and a gold-nickel oxide layer disposed on the second surface.

In one embodiment of the present invention, the perovskite material layer is formed by CH₃NH₃PbI₃, CH₃NH₃PbIₓCl₃₋ₓ, or HC(NH₂)₂PbI₃, wherein x is 0, 1, or 2.

In one embodiment of the present invention, the gold-nickel oxide layer comprises a gold (Au) network structure embedded in nickel oxides.

In one embodiment of the present invention, the perovskite solar cell further comprises a transparent substrate having a surface on which the gold-nickel oxide layer is disposed.

In one embodiment of the present invention, the transparent substrate is a glass substrate.

In one embodiment of the present invention, the gold-nickel oxide layer has a thickness less than or equal to 50 nm.

In one embodiment of the present invention, the electron transport layer is fullerene, ZnO, TiO₂, or [6.6]-phenyl-C61-butyric acid methyl ester (PCBM).

To achieve the above objects, another embodiment according to the present invention provides a manufacturing method of a perovskite solar cell, comprising steps of providing a transparent substrate; forming a gold-nickel oxide layer on the transparent substrate; and forming a perovskite material layer on the gold-nickel oxide layer.

In one embodiment of the present invention, the gold-nickel oxide layer is formed by steps of forming a nickel layer on the transparent substrate; forming a gold layer on the nickel layer; and treating the transparent substrate, the nickel layer, and the gold layer in oxygen atmosphere by a thermal annealing process to form a gold (Au) network structure embedded in nickel oxides (NiOₓ).

In one embodiment of the present invention, the transparent substrate is a glass substrate and the thermal annealing process has a temperature ranged from 350 to 550° C.

In one embodiment of the present invention, the nickel layer and the gold layer are formed by an electron beam evaporation.

In one embodiment of the present invention, the thickness of the nickel layer and the thickness of the gold layer are both less than 20 nm.

In one embodiment of the present invention, the perovskite material layer is formed by an organolead iodide compound having molecular formula of CH₃NH₃PbI₃, CH₃NH₃PbIₓCl₃₋ₓ, HC(NH₂)₂PbI₃, wherein x is 0, 1, or 2.

In one embodiment of the present invention, after forming the perovskite material layer, the manufacturing method further comprising a step of forming an electron transport layer on the perovskite material layer.

In one embodiment of the present invention, the electron transport layer is fullerene, ZnO, TiO₂, or [6.6]-phenyl-C61-butyric acid methyl ester.

### BRIEF DESCRIPTION OF THE DRAWINGS

FIG. 1 is a schematic view of a perovskite solar cell according to one embodiment of the present invention.

FIGS. 2A to 2C show the mechanism of forming a gold-nickel oxide layer according to one embodiment of the present invention.

FIGS. 3A to 3B are SEM photos for showing the surface profile and the cross-sectional structure of the gold-nickel oxide layer according to one embodiment of the present invention.

FIG. 4 shows the transmittance of the gold-nickel oxide layer in Comparison 1 and Experiments 1 to 5.

FIG. 5 shows the work function trend of the gold-nickel oxide layer in Experiment 1 to 4.

### DETAILED DESCRIPTION OF THE PREFERRED EMBODIMENTS

The structure and the technical means adopted by the present invention to achieve the above and other objects can be best understood by referring to the following detailed description of the preferred embodiments. Furthermore, if there is no specific description in the invention, singular terms such as “a”, “one”, and “the” include the plural number. For example, “a compound” or “at least one compound” may include a plurality of compounds, and the mixtures thereof. If there is no specific description in the invention, “%” means “weight percentage (wt %)”, and the numerical range (e.g. 10%˜11% of A) contains the upper and lower limit (i.e. 10%≦A≦11%). If the lower limit is not defined in the range (e.g. less than, or below 0.2% of B), it means that the lower limit may be 0 (i.e. 0%≦B≦0.2%). The proportion of “weight percent” of each component can be replaced by the proportion of “weight portion” thereof. The abovementioned terms are used to describe and understand the present invention, but the present invention is not limited thereto.

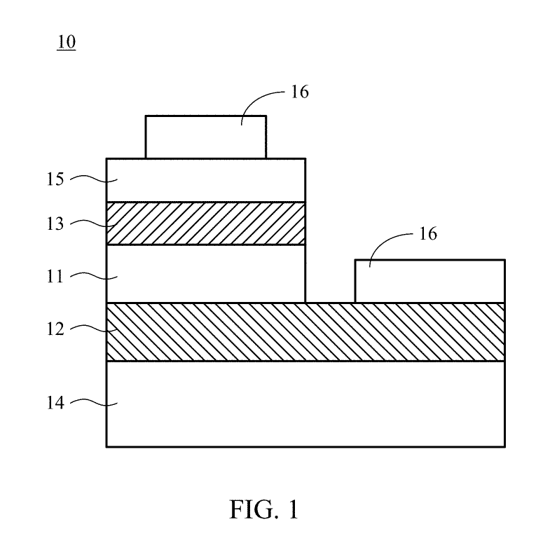

Referring to FIG. 1, one embodiment of the present invention provides a perovskite solar cell 10, mainly comprising a perovskite material layer 11 having a first surface and a second surface opposite to each other; an electron transport layer 13 disposed on the first surface; and a gold-nickel oxide layer 12 disposed on the second surface. The perovskite solar cell 10 has a layer-stacked structure, and each interface between the layers is substantially flat.

The perovskite material layer 11 is an organic/inorganic hybrid photosensitive material, preferably, having the molecular formula of CH₃NH₃PbI₃, CH₃NH₃PbIₓCl₃₋ₓ, or HC(NH₂)₂PbI₃. The gold-nickel oxide layer 12 has good optical transparency, so that the sunlight passes through the gold-nickel oxide layer 12, and then being absorbed by the perovskite material layer 11 to generate electrons and holes. The gold-nickel oxide layer 12 comprises a composite layer formed by gold and nickel oxides. The gold-nickel oxide layer 12 can comprises a gold (Au) network structure embedded in nickel oxides (NiO_{X}). The gold-nickel oxide layer 12 has a thickness less than or equal to 50 nm, such as 10 to 50 nm, preferably 20 to 45 nm, for example, 25, 30, or 40 nm, but it is not limited thereto.

Preferably, the perovskite solar cell 10 further includes a transparent substrate 14, so that the gold-nickel oxide layer 12 can be disposed on a surface of the transparent substrate 14. That is, the gold-nickel oxide layer 12 is disposed between the transparent substrate 14 and the perovskite material layer 11. The gold (Au) network structure of the gold-nickel oxide layer 12 embedded in the nickel oxides (NiO_{X}), means that the NiO_{X} abuts the perovskite material layer 11; and the Au network structure of the gold-nickel oxide layer 12 is relatively near the transparent substrate 14 (i.e. relatively far from the perovskite material layer 11). The transparent substrate 14 is for example a glass substrate.

In addition, a well-known material of the electron transport material, such as fullerene, ZnO, TiO₂, or [6,6]-phenyl-C61-butyric acid methyl ester (PCBM), are able to be used as the electron transport layer 13.

Furthermore, as shown in FIG. 1, the perovskite solar cell 10 generally includes an electron buffer layer 15 and a metallic electrode 16. The electron buffer layer 15 is disposed on a surface of the electron transport layer 13, such as BCP (bathocuproine), but it is not limited thereto, the BCP can be replaced with any electron transport material which is generally applied to a solar cell. The metallic electrode 16 can be disposed on the electron buffer layer 15 as a cathode, and another metallic electrode 16 is disposed on the gold-nickel oxide layer 12 as an anode. The metallic electrode 16 is for example an aluminum electrode, but it is not limited thereto. The sunlight can pass through the gold-nickel oxide layer 12 and the transparent substrate 14 then enter the perovskite solar cell 10 so as to be converted into electrons and holes to generate a potential trend. Thereafter, the metallic electrode 16 can be conducted by a suitable loop.

A manufacturing method of the perovskite solar cell 10 according to another embodiment of the present invention is provided, mainly comprising steps of: (1) providing a transparent substrate 14; (2) forming a gold-nickel oxide layer 12 on the transparent substrate 14; and (3) forming a perovskite material layer 11 on the gold-nickel oxide layer 12.

In the step (1), the transparent substrate 14 is a heat-resistant transparent substrate, and preferably a glass substrate, but it is not limited thereto.

In the step (2), the gold-nickel oxide layer 12 can be formed by steps of: (2a) forming a nickel (Ni) layer on the transparent substrate 14; (2b) forming a gold (Au) layer on the nickel layer; and (2c) treating the transparent substrate 14, the nickel layer, and the gold layer in oxygen atmosphere by a thermal annealing process so as to form a gold (Au) network structure embedded in nickel oxides. In this step, the temperature of the thermal annealing process can be 350 to 550° C., for example, 350, 450, 500, or 550° C., but it is not limited thereto. The duration of the thermal annealing process can be 3 to 10 minutes, for example, 3, 4, 5, 6, 7, 9, or 10 minutes, but it is not limited thereto. The nickel layer and the gold layer can be formed by using an electron beam evaporation. The thickness of the nickel layer and the thickness of the gold layer are less than 20 nm, for example, 7, 10, 15, or 20 nm, but they are not limited thereto. Preferably, the thickness of the nickel layer is 10 nm, and the thickness of the gold layer is 5 or 7 nm.

In the step (3), the perovskite material layer 11 is formed by an organolead iodide compound having a molecular formula of CH₃NH₃PbI₃, CH₃NH₃PbIₓCl₃₋ₓ, or HC(NH₂)₂PbI₃, wherein x is 0, 1, or 2. In this step, the perovskite material layer 11 can be formed by the following steps: preparing a solution of an organolead iodide compound, and then the solution is applied on the gold-nickel oxide layer 12 with a rotation speed of 1000 rpm for 20 seconds. Next, the solution is stopped adding, and the rotation speed is adjusted to 4000 rpm and kept for 25 seconds to allow the solution of the organolead iodide compound being distributed uniformly on the gold-nickel oxide layer 12 so as to form an organolead iodide film. Next, the rotation speed is kept at 4000 rpm and the organolead iodide film is blown by nitrogen gas for 35 seconds. Finally, the organolead iodide film is treated by a thermal annealing process at 100° C.

Furthermore, after the perovskite material layer 11 is formed, the manufacturing method can comprises a step of forming an electron transport layer 13 on the perovskite material layer 11. The electron transport layer 13 can be selected from a group consisting of fullerene, ZnO, TiO₂, or PCBM.

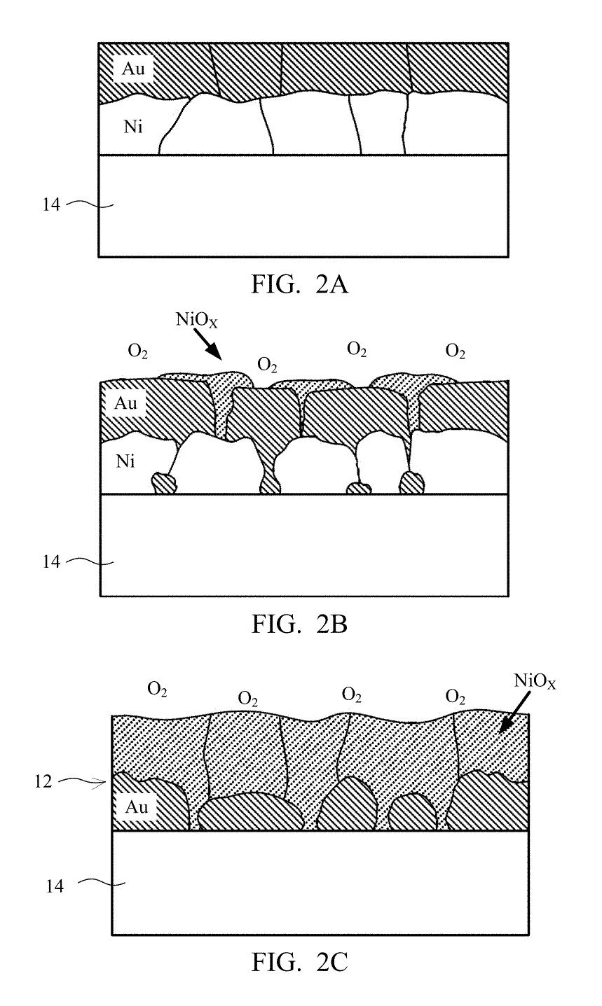

Referring to FIG. 2A to 2C, which show the mechanism of forming the gold-nickel oxide layer 12. As shown in FIG. 2A, the nickel layer and the gold layer are formed on the transparent substrate 14 in sequence by an electron beam evaporation. Next, as shown in FIG. 2, when performing the thermal annealing process within enough oxygen (O₂), atomic diffusion within the gold layer and the nickel layer will occur. Ni leaked from the grain boundary of the gold layer reacts with oxygen gas to form nickel oxides (NiO_{X}). When more and more nickel oxides deposits at the grain boundary of the gold layer, the Au which cannot be oxidized is pushed down and deposited on the transparent substrate 14. Finally, the Au network structure embedded in the nickel oxides as shown in FIG. 2C is obtained.

The present invention further provides actual test data and analysis to demonstrate the structure and efficiency of the perovskite solar cell according to the above embodiments.

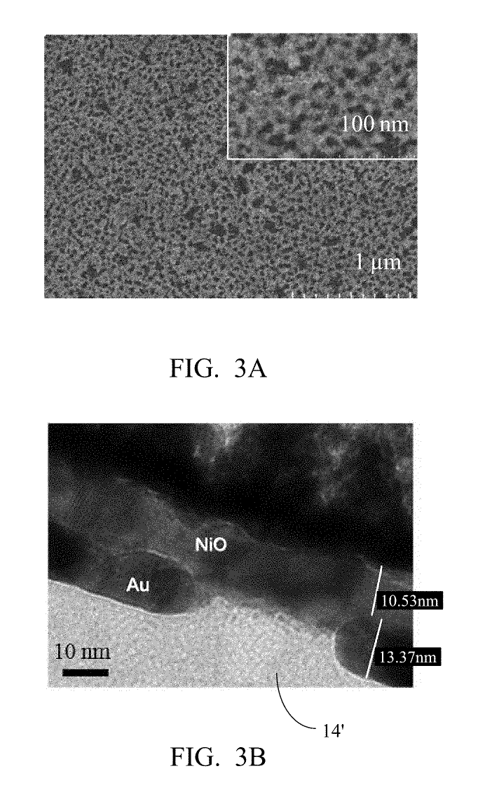

Referring to FIGS. 3A and 3B, both of them show the surface profile and cross-sectional structure of the gold-nickel oxide layer (Au:NiO_{X}) observed by scanning electron microscope (SEM) after the thermal annealing process at 500° C. for 5 minutes. It can be seen from FIG. 3A that the surface profile of the Au:NiO_{X} has the gold network structure and the islands of nickel oxides. In FIG. 2B, the nickel oxides (NiO_{X}) formed from the Ni layer at the bottom push the gold down to the glass substrate 14′. In the SEM images, the nickel oxides (NiO_{X}) show dark gray (black), and the lighter portion is Au.

Referring to Table 1, which shows photovoltaic parameters of perovskite-based cells with the gold-nickel oxide layer was prepared by thermally oxidizing at different temperatures. The comparison is perovskite-based cells with ITO/PEDOT:PSS substrate Wherein, 7Au:NiO_{X} represents the gold-nickel oxide layer formed by 7 nm gold layer and 10 nm nickel layer after the thermal annealing process, and 5Au: NiO_{X} represents the gold-nickel oxide layer formed by 5 nm gold layer and 10 nm nickel layer after the thermal annealing process.

TABLE 1

| | | Voc | Jsc | | PCE |
|---|---|---|---|---|---|
| Group | Layer structure | (V) | (mA cm⁻²) | FF | (%) |
| Comparison | ITO/PEDOT:PSS | 0.90 | 16.29 | 0.74 | 10.85 |
| Experiment 1 | 7Au:NiO_{X}/350° C. | 0.98 | 7.16 | 0.59 | 4.15 |
| Experiment 2 | 7Au:NiO_{X}/450° C. | 1.01 | 13.14 | 0.65 | 8.65 |
| Experiment 3 | 7Au:NiO_{X}/500° C. | 1.02 | 13.04 | 0.77 | 10.24 |
| Experiment 4 | 7Au:NiO_{X}/550° C. | 0.98 | 12.86 | 0.57 | 7.20 |
| Experiment 5 | 5Au:NiO_{X}/500° C. | 1.00 | 12.61 | 0.56 | 7.09 |

From Table 1, the gold-nickel oxide layers formed at different temperatures, even by the gold layer and the nickel layer with the same thickness in Experiment 1 to 4, still have great differences in the photovoltaic parameters. The perovskite-based cells with gold-nickel oxide layer in Experiment 3 which is obtained by the thermal annealing process at 500° C. has the best power conversion efficiency (PCE) about 10.24%, which is quite close to the PCE of perovskite-based cells with transparent conductive film ITO and the hole transport layer PEDOT:PSS.

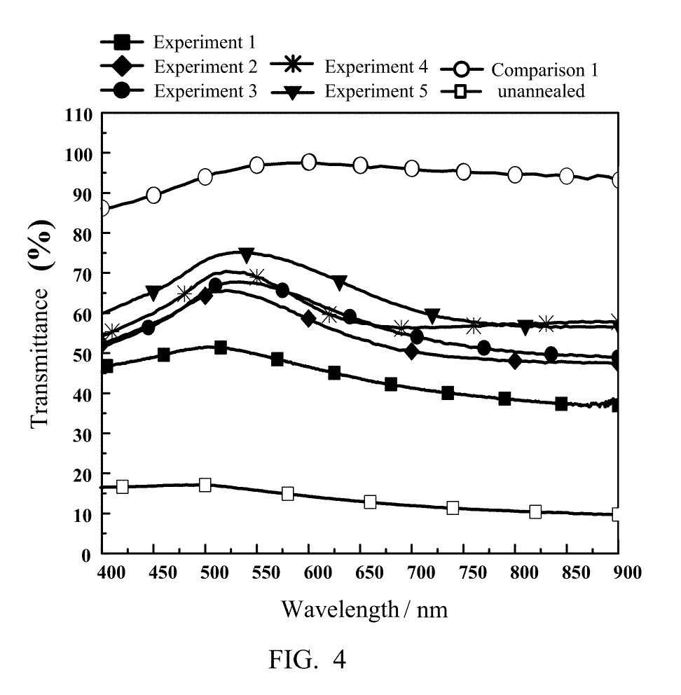

Referring to FIG. 4, which shows the transmittance of the gold-nickel oxide layer in Comparison 1 and Experiment 1 to 4. In addition, the transmittance of the gold layer and the nickel layer before the thermal annealing process are measured to provide a comparison. From FIG. 4, it can be observed that the opaque gold layer and nickel layer (marked as “unannealed”) can be transferred into the gold-nickel oxide layer with a transmittance of about 40% (Experiment 1) after the thermal annealing process. Moreover, the transmittance can be raised to about 70% (Experiment 3-5) by the increased temperature of the thermal annealing process. In addition, from Experiment 3 and Experiment 5, it can be understood that the transmittance of the gold-nickel oxide layer formed by 5 nm/10 nm of gold layer/nickel layer in Experiment 5 has higher transmittance after the thermal annealing process at 500° C. The transmittance of Experiment 5 is about 10% higher than that of Experiment 3.

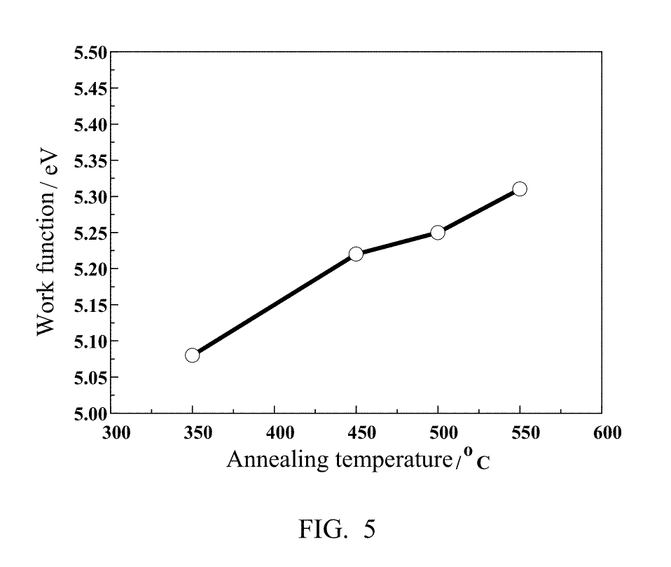

Referring to FIG. 5, which shows the work function respectively in the abovementioned Experiment 1 to 4. From FIG. 5, the work functions are gradually increased with the temperature of the thermal annealing process from 350° C. to 550° C. The work function at 500° C. is about 5.25 eV.

According to the perovskite solar cell and the manufacturing method of the present invention, the gold-nickel oxide layer has excellent transmittance which can reach to about 70% after the thermal annealing process at 500° C., and has the work function of about 5.25 eV to be compatible with the perovskite material. Because the gold-nickel oxide layer contains NiO_{X} which has a work function of 5.4 eV compatible with the perovskite material, the hole transport energy loss thereof is less than that of the PEDOT:PSS with the work function of 5.1 eV, and thus the gold-nickel oxide layer is more suitable for hole extraction, and has chemical stability and electron blocking ability. Furthermore, although NiO_{X} is very suitable for the hole transport material of the perovskite solar cell, the NiO_{X} still has poor electrical characteristics. Therefore, the present invention provides double-layered Ni/Au formed on the glass substrate by the electron beam evaporation, and then the double-layered Ni/Au is annealed at a high temperature and oxidized to form Au:NiO_{X} which can replace the traditional ITO used as a transparent electrode. The Au:NiO_{X} can directly form an excellent heterojunction with the perovskite material layer, and the hole transport layer is not essential.

The present invention has been described with preferred embodiments thereof and it is understood that many changes and modifications to the described embodiments can be carried out without departing from the scope and the spirit of the invention that is intended to be limited only by the appended claims.

1. A perovskite solar cell, comprising:
a perovskite material layer having a first surface and a second surface opposite to each other;
an electron transport layer disposed on the first surface;
a gold-nickel oxide layer disposed on the second surface; and
a transparent substrate having a surface on which the gold-nickel oxide layer is disposed;
wherein the gold-nickel oxide layer comprises a gold (Au) network structure embedded in nickel oxides (NiO_{X}) and deposited on the transparent substrate.

2. The perovskite solar cell according to claim 1, wherein the perovskite material layer is formed by CH₃NH₃PbI₃, CH₃NH₃PbIₓCl₃₋ₓ or HC(NH₂)₂PbI₃, wherein x is 0, 1, or 2.

3-4. (canceled)

5. The perovskite solar cell according to claim 1, wherein the transparent substrate is a glass substrate.

6. The perovskite solar cell according to claim 1, wherein the gold-nickel oxide layer has a thickness less than or equal to 50 nm.

7. The perovskite solar cell according to claim 1, wherein the electron transport layer is fullerene, ZnO, TiO₂ or [6.6]-phenyl-C61-butyric acid methyl ester.
